(19) United States
(12) Patent Application Publication
(10) Pub. No.: US 2002/0126546 A1
(43) Pub. Date: Sep. 12, 2002

(54) Apparatus and method for securing recording medium driver

(76) Inventors: Jung-Hyuk Im, Seoul (KR); Tae-Young Ahn, Donghae-city (KR)

Correspondence Address: Daniel F. Drexler, 55 Griffin South Road, Bloomfield, CT, 06002, US

(21) Appl. No.: 10/005,284

(22) Filed: Dec. 5, 2001

(30) Foreign Application Priority Data
Jan. 5, 2001 (KR) 2001-677

(51) Int. Cl. G11C 29/00

(52) U.S. Cl. 365/200

(57) ABSTRACT

A security device of a recording medium driver is provided, which encrypts data from an interface port of a computer main board and inputs the encrypted data to an interface port of the recording medium driver, and decrypts the data from the interface port of the recording medium driver and inputs the decrypted data to the interface port of the computer main board. The security device includes an encrypter, a decrypter and a memory. The encrypter encrypts the data provided from the interface port of the computer main board using a logic circuit and inputs the encrypted data to the interface port of the recording medium driver. The decrypter decrypts the data provided from the interface port of the recording medium driver using a logic circuit and inputs the decrypted data to the interface port of the computer main board. The memory receives data to be used for encrypting from a user and provides the received data to the encrypter and the decrypter.

### BACKGROUND OF THE INVENTION

1. Field of the Invention

The present invention relates to an apparatus and a method for securing a recording medium driver, and more particularly, to an apparatus and a method for securing a recording medium driver that records and reads data on a recording medium such as a hard disc or a Compact Disk-Read Only Memory (CD-ROM).

2. Description of the Related Art

FIG. 1 shows an interface between a computer main board 1 and a recording medium driver 2 in a computer. As shown in FIG. 1, the computer main board 1 and the recording medium driver 2 have interface ports 11 and 21, respectively, such as an Advanced Technology Attachment (ATA) port or a Small Computer System Interface (SCSI) port. The interface ports 11 and 21 interface with each other via an ATA bus 3 or an SCSI bus. The ATA is a standard 16-bit interface, known to a computer industry as Integrated Drive Electronics (IDE), and a formal name used by X3T10 Group of American National Standards Institute (ANSI). The SCSI is also a standard 16-bit interface to be adopted by ANSI.

The typical interface shown in FIG. 1 does not have an apparatus to guarantee security for the recording medium driver 2. Therefore, if the recording medium driver 2 is stolen, the information saved in the recording medium driver 2 may be used illegally by an unauthorized person.

### SUMMARY OF THE INVENTION

To solve the above-described problem, it is an object of the present invention to provide an apparatus and a method for securing a recording medium driver that can prevent the saved information from being read by an unauthorized person even if the computer recording medium driver is stolen.

To achieve the objective, according to the present invention, an apparatus for securing the recording medium driver encrypts data from the interface port of the computer main board and inputs the encrypted data to the interface port of the recording medium driver, and decrypts the data from the interface port of the recording medium driver and inputs the decrypted data to the interface port of the computer main board.

The apparatus for securing the recording medium driver (hereinafter referred to as a security device) includes:

an encrypter for encrypting the data from the interface port of the computer main board using a logic circuit and inputting the encrypted data to the interface port of the recording medium driver;

a decrypter for decrypting the data from the interface port of the recording medium driver using a logic circuit and inputting the decrypted data to the interface port of the computer main board; and

a memory for receiving data to be used for encrypting from a user and providing the received data to the encrypter and the decrypter.

In the security device of the recording medium driver, the encrypter and the decrypter encrypts and decrypts the data by the data for encrypting from the memory, using the logic circuits respectively. Therefore, even if the recording medium driver is stolen, the information saved in the recording medium driver cannot be read illegally by an unauthorized person.

Preferably, a key input interface is connected to the register. When a user inserts a key of an EEPROM, where the data to be used for encrypting is saved, into the key input interface, the data to be used for encrypting is inputted to the register. Because only the user has the key of an EEPROM, the security device cannot be used illegally.

To achieve the above objective, a method for securing a recording medium driver (hereinafter referred to as a security method) by encrypting 16-bit data provided from an interface port of a computer main board and inputting the encrypted data to an interface port of the recording medium driver, the security method includes steps of:

saving data to be used for encrypting in a memory in such a way that different data can be saved without any identical data;

reading 8-bit data of an address which has the same value as 4-bit data in 16-bit data provided from the interface port of the computer main board, from the memory; and

replacing 8-bit data of the 16-bit data provided from the interface port of the computer main board with the 8-bit data created as a result of a logic operation performed on 8-bit data of the 16-bit data provided from the interface port of the computer main board and the 8-bit data read from the memory.

According to the security method, the data to be used for encrypting, which is saved in the saving step, is used in the replacing step. Therefore, even if the recording medium driver is stolen, the information saved in the recording medium driver cannot be read illegally by an unauthorized person.

Preferably, reading and replacing are performed by relevant logic circuits. Therefore, the security for the recording medium driver can be enhanced.

### BRIEF DESCRIPTION OF THE DRAWINGS

The above object and advantages of the present invention will become more apparent by describing in detail a preferred embodiment thereof with reference to the attached drawings in which:

FIG. 1 is a block diagram showing an interface between a computer main board and a recording medium driver in a computer;

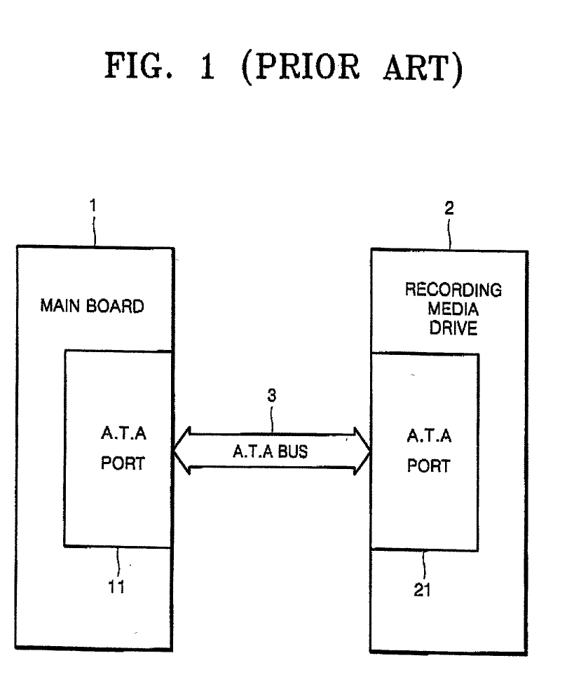

FIG. 2 is a block diagram showing a security device of the recording medium driver according to an embodiment of the present invention; and

FIG. 3 is a flow diagram showing the operation procedure of an encrypter of FIG. 2.

### DETAILED DESCRIPTION OF THE INVENTION

The present invention will now be described in detail by describing a preferred embodiment thereof with reference to the accompanying drawings.

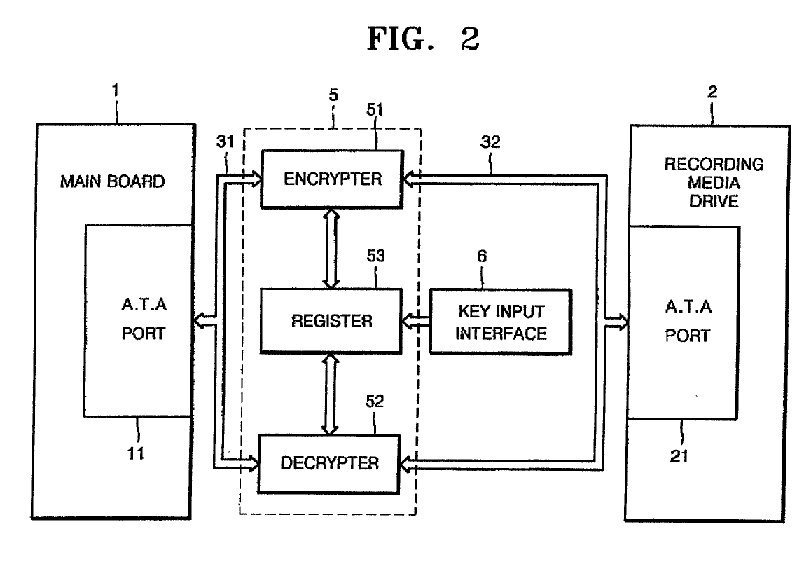

Referring to FIG. 2, a security device 5 and a key input interface 6 of a recording medium driver 2 according to an embodiment of the present invention are connected with each other via buses 31 and 32 which interface with interface ports 11 and 21. Here, the buses 31 and 32 may be ATA buses or SCSI buses interfacing with ATA ports or SCSI ports respectively.

The security device 5 of the present invention encrypts the data from an interface port 11 of a computer main board 1 and inputs the encrypted data to the interface port 21 of the recording medium driver 2, and decrypts the data from the interface port 21 of the recording medium driver 2 and inputs the decrypted data to the interface port 11 of the computer main board 1. The security device 5 includes an encrypter 51, a decrypter 52 and a register 53 acting as a memory. The key input interface 6 is connected to the register 53 acting as a memory. When a user inserts a key (not shown) of an EEPROM, where data to be used for encrypting is saved in such a way that different data can be saved without any identical data, into the key input interface 6, the data to be used for encrypting is inputted to the register 53 acting as a memory.

The encrypter 51 encrypts the data from the interface port 11 of the computer main board 1, using a logic circuit, and inputs the encrypted data to the interface port 21 of the recording medium driver 2. The decrypter 52 decrypts the data from the interface port 21 of the recording medium driver 2, using a logic circuit, and inputs the decrypted data to the interface port 11 of the computer main board 1. The register 53 acting as a memory provides the data from the key input interface 6 to the encrypter 51 and the decrypter 52.

In the security device 5 of the recording medium driver shown in FIG. 2, the encrypter 51 and the decrypter 52 receive the data to be used for encrypting from the register 53 and perform encryption and decryption, respectively, using logic circuits. Therefore, even if the recording medium driver 2 is stolen, the data saved in the recording medium driver 2 cannot be read illegally by an unauthorized person. In addition, if the user inserts the key (not shown) of the EEPROM, where the data to be used for encrypting is saved in such a way that different data can be saved without any identical data, into the key input interface 6, the data to be used for encrypting is inputted to the register 53 as a memory. Because only the user has the key of the EEPROM, security for the security device 5 can be guaranteed.

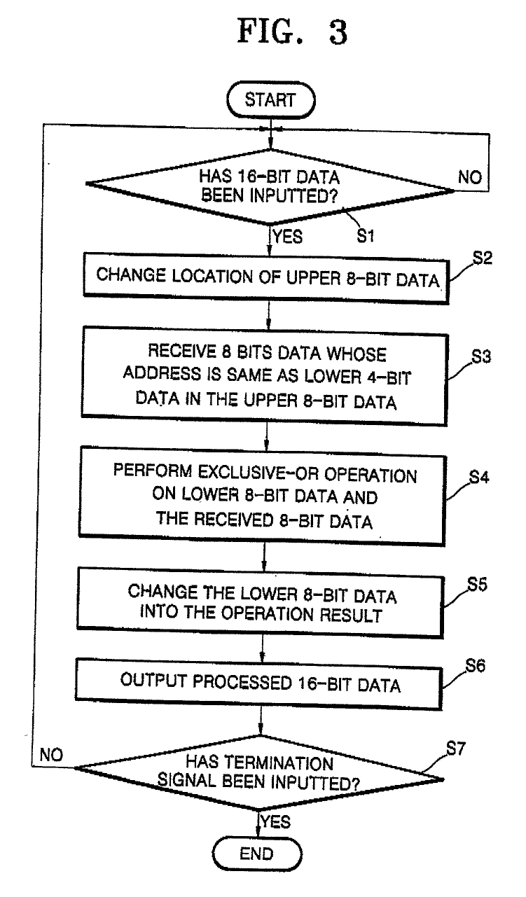

FIG. 3 shows the operation of the encrypter 51 of the security device 5 shown in FIG. 2. The operation process to be explained below is performed by an Application-Specific Integrated Circuit (ASIC) in the encrypter 51. The decrypter 52 shown in FIG. 2 performs the reverse of the encryption operation to be explained below.

For easy understanding, it is assumed that, as shown Table 1, the interface port 11 of the computer main board 1 inputs 16-bit data to the encrypter 51.

TABLE 1

| | | | | | | | | | | | | | | | | |
|---|---|---|---|---|---|---|---|---|---|---|---|---|---|---|---|---|
| Bit Location | F | E | D | C | B | A | 9 | 8 | 7 | 6 | 5 | 4 | 3 | 2 | 1 | 0 |
| Data | 1 | 0 | 1 | 1 | 0 | 1 | 0 | 1 | 1 | 0 | 1 | 0 | 0 | 1 | 0 | 1 |

In Table 1, F′ indicates the position of the Most Significant Bit (2¹⁵) and ‘0’ indicates the position of the Least Significant Bit (2⁰). Therefore, in terms of a hexadecimal number, the data of Table 1 is marked as ‘B5A5’.

If the 16-bit data shown in Table 1 is determined in step S1 to be inputted to the encrypter 51 from the interface port 11 of the computer main board 1, the positions of the data within the upper 8-bit data “10110101 (B5)” are changed in step S2. To be more specific, ‘F’ (2¹⁵), ‘D’ (2¹³), ‘B’ (2¹¹) and ‘A’ (2¹⁰) exchange their positions with ‘E’ (2¹⁴), ‘C’ (2¹²), ‘8’ (2⁸) and ‘9’ (2⁹) respectively. The result is shown in Table 2.

TABLE 2

| | | | | | | | | | | | | | | | | |
|---|---|---|---|---|---|---|---|---|---|---|---|---|---|---|---|---|
| Changed bit position | E | F | C | D | 8 | 9 | A | B | 7 | 6 | 5 | 4 | 3 | 2 | 1 | 0 |
| Changed data | 0 | 1 | 1 | 1 | 1 | 0 | 1 | 0 | 1 | 0 | 1 | 0 | 0 | 1 | 0 | 1 |

Next, the register 53 provides 8-bit data, which has the same value address as the lower 4-bit data “1010” of the upper 8-bit data “01111010”, to the encrypter 51 in step S3. Here, it is assumed that the data inputted from the register 53 to the encrypter 51 is “00000110”.

Then, an exclusive-OR operation is performed on the lower 8-bit data “10100101” and the 8-bit data “00000110” inputted by the register 53 in step S4. As a result of the step S4, “10100011” is outputted and replaces the lower 8-bit data in step S5.

The processed 16-bit data is outputted from the encrypter 51 and provided through the interface bus 32 to the interface port 21 of the recording medium driver 2 in step S6.

The above process procedure can be summarized as shown in Table 3.

TABLE 3

| | | | | | | | | | | | | | | | | |
|---|---|---|---|---|---|---|---|---|---|---|---|---|---|---|---|---|
| Input bit position | F | E | D | C | B | A | 9 | 8 | 7 | 6 | 5 | 4 | 3 | 2 | 1 | 0 |
| Input data | 1 | 0 | 1 | 1 | 0 | 1 | 0 | 1 | 1 | 0 | 1 | 0 | 0 | 1 | 0 | 1 |
| Changed bit | E | F | C | D | 8 | 9 | A | B | 7 | 6 | 5 | 4 | 3 | 2 | 1 | 0 |
| position | | | | | | | | | | | | | | | | |
| Semi-processed | 0 | 1 | 1 | 1 | 1 | 0 | 1 | 0 | 1 | 0 | 1 | 0 | 0 | 1 | 0 | 1 |
| data | | | | | | | | | | | | | | | | |
| Data to be used | | | | | | | | | 0 | 0 | 0 | 0 | 0 | 1 | 1 | 0 |
| for encrypting | | | | | | | | | | | | | | | | |
| Output data | 0 | 1 | 1 | 1 | 1 | 0 | 1 | 0 | 1 | 0 | 1 | 0 | 0 | 0 | 1 | 1 |

The above steps (S1 through S6) are repeated until a completion signal is inputted in step S7. If the encrypter and the decrypter receive the data to be used for encrypting from the register 53, they perform encryption and decryption. Therefore, even if the recording medium driver 2 is stolen, the data saved in the recording medium driver 2 cannot be used illegally by an unauthorized person. If the user inserts the key of the EEPROM into the key input interface 6, the data to be used for encrypting is provided to the register 53. Because only the user has the key of the EEPROM, security for the security device 5 can be enhanced.

As described above, in the recording medium driver according to the present invention, the encrypter and the decrypter receive the data to be used for encrypting from the register, using the logic circuits. Therefore, even if the recording medium driver is stolen, the information saved in the recording medium driver cannot be used illegally by an unauthorized person.

Although a specific embodiment of the invention has been described herein for illustrative purposes, various modifications and equivalents thereof can be made without departing from the spirit and scope of the invention, as will be recognized by those skilled in the relevant art. Accordingly, the invention is not limited the disclosure, but instead its scope is to be determined entirely by the following claims.

What is claimed is:

1. An apparatus for securing a recording medium driver, which encrypts data provided from an interface port of a computer main board and inputs the encrypted data to an interface port of the recording medium driver, and decrypts the data provided from an interface port of the recording medium driver and inputs the decrypted data to the interface port of the computer main board, the apparatus comprising:
an encrypter for encrypting the data provided from the interface port of the computer main board using a logic circuit and inputting the encrypted data to the interface port of the recording medium driver;
a decrypter for decrypting the data provided from the interface port of the recording medium driver using a logic circuit and inputting the decrypted data to the interface port of the computer main board; and
a memory for receiving data to be used for encrypting from a user and providing the received data to the encrypter and the decrypter.

2. The apparatus of claim 1, further comprising;
a key input interface connected to the memory,
Wherein, when a user inserts a key of an EEPROM, where the data to be used for encrypting is saved, into the key input interface, the data to be used for encrypting is inputted to the memory.

3. A method for securing a recording medium driver by encrypting 16-bit data provided from an interface port of a computer main board and inputting the encrypted data to an interface port of the recording medium driver, the method comprising:
saving data to be used for encrypting in a memory in such a way that different data can be saved without any identical data;
reading 8-bit data of an address which has the same value as 4-bit data in 16-bit data provided from the interface port of the computer main board, from the memory; and
replacing 8-bit data of the 16-bit data provided from the interface port of the computer main board with the 8-bit data created as a result of a logic operation performed on 8-bit data of the 16-bit data provided from the interface port of the computer main board and the 8-bit data read from the memory.

4. The method of claim 3, wherein reading and replacing are performed by relevant logic circuits.

5. The method of claim 3, wherein the interface port can be either an Advanced Technology Attachment (ATA) port or a Small Computer System Interface (SCSI) port.
